(19) United States
(12) Patent Application Publication
(10) Pub. No.: US 2017/0011907 A1
(43) Pub. Date: Jan. 12, 2017

(54) SUBSTRATE PROCESSING METHOD, SUBSTRATE PROCESSING APPARATUS, AND STORAGE MEDIUM

(71) Applicant: Tokyo Electron Limited, Tokyo (JP)

(72) Inventors: Kazuyuki Mitsuoka, Kumamoto (JP); Hiroki Ohno, Kumamoto (JP); Gentaro Goshi, Kumamoto (JP); Hisashi Kawano, Kumamoto (JP)

(21) Appl. No.: 15/201,942

(22) Filed: Jul. 5, 2016

(30) Foreign Application Priority Data
Jul. 10, 2015 (JP) 2015-139011

(51) Int. Cl. H01L 21/02

(52) U.S. Cl. CPC H01L 21/02101; H01L 21/02057

(57) ABSTRACT

Disclosed is a substrate processing method including: supplying a first solvent including a fluorine-free organic solvent, to a workpiece; supplying a second solvent including a fluorine-containing organic solvent that is not dissolved with the first solvent at a normal temperature, and is dissolved with the first solvent at a temperature higher than the normal temperature; and replacing the first solvent with the second solvent while dissolving the first solvent and the second solvent by heating the first solvent and the second solvent to a dissolution temperature or higher.

### CROSS-REFERENCE TO RELATED APPLICATIONS

This application is based on and claims priority from Japanese Patent Application No. 2015-139011 filed on Jul. 10, 2015 with the Japan Patent Office, the disclosure of which is incorporated herein in its entirety by reference.

### TECHNICAL FIELD

The present disclosure relates to a substrate processing method, a substrate processing apparatus, and a storage medium for use in a supercritical drying of a substrate.

### BACKGROUND

In a semiconductor device manufacturing process of forming a laminated structure of an integrated circuit on a front surface of a semiconductor wafer (hereinafter, referred to as a “wafer”) which is a substrate, when removing a liquid attached to the front surface of the wafer in a liquid processing step with a cleaning liquid such as, for example, a chemical liquid, a phenomenon in which a pattern formed on the wafer collapses due to the surface tension of the liquid (hereinafter, referred to as a “pattern collapse”), has become a problem.

As a method for removing the liquid attached to the front surface of the wafer while suppressing generation of the pattern collapse, a method using a fluid in a supercritical state has been known. The fluid in a supercritical state has a low viscosity and a high liquid extraction ability as compared with the liquid. Further, no interface exists between the fluid in a supercritical state and a liquid or gas in equilibrium. Therefore, when the liquid attached to the front surface of the wafer is replaced with a fluid in a supercritical state, and then, the fluid in a supercritical state is changed to a gas, the liquid may be dried without being affected by the surface tension.

For example, in Japanese Patent Laid-Open Publication No. 2014-022566, fluorine-containing organic solvents (which are different in viscosity in the publication) are used in both a dry-prevention liquid and a fluid in a supercritical state, from the viewpoints of a high degree of replacement of the liquid and the fluid in a supercritical state, suppression of moisture from entering into a supercritical drying chamber, or volatilization of a dry-preventing fluorine-containing organic solvent until a substrate is carried into a processing container, and suppression of decomposition of the fluorine-containing organic solvent. Further, the fluorine-containing organic solvent is also suitable as a dry-preventing liquid in terms of flame retardancy.

However, in order to replace the liquid attached to the front surface of the wafer with the fluid in a supercritical state, a plurality of (e.g., two or more) fluorine-containing organic solvents have been used in consideration of a high degree of replacement. However, the fluorine-containing organic solvents are expensive, and thus, reducing the kinds of the fluorine-containing organic solvents to be used is required.

### SUMMARY

The present disclosure provides a substrate processing method including: supplying a first solvent including a fluorine-free organic solvent, to a workpiece; supplying a second solvent including a fluorine-containing organic solvent that is not dissolved with the first solvent at a normal temperature, and is dissolved with the first solvent at a temperature higher than the normal temperature; and replacing the first solvent with the second solvent while dissolving the first solvent and the second solvent by heating the first solvent and the second solvent to a dissolution temperature or higher.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional plan view of a liquid processing apparatus.

FIG. 2 is a vertical-sectional side view of a liquid processing unit provided in the liquid processing apparatus.

FIG. 3 is a block diagram of a supercritical processing unit provided in the liquid processing apparatus.

FIG. 4 is an external perspective view of a processing container of the supercritical processing unit.

FIG. 5 is a view illustrating an action of the present exemplary embodiment.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

An object of the present disclosure is to provide a substrate processing method, a substrate processing apparatus, and a storage medium for reducing the kinds of fluorine-containing organic solvents to be used to replace a liquid attached to a front surface of a wafer with a fluid in a supercritical state.

The present disclosure provides a substrate processing method including: supplying a first solvent including a fluorine-free organic solvent, to a workpiece; supplying a second solvent including a fluorine-containing organic solvent that is not dissolved with the first solvent at a normal temperature, and is dissolved with the first solvent at a temperature higher than the normal temperature; and replacing the first solvent with the second solvent while dissolving the first solvent and the second solvent by heating the first solvent and the second solvent to a dissolution temperature or higher.

In the above-described substrate processing method, the dissolution temperature of the first solvent and the second solvent is 40° C. or higher.

In the above-described substrate processing method, the first solvent and the second solvent are heated by heating the workpiece.

In the above-described substrate processing method, the first solvent and the second solvent are heated by supplying the second solvent at a high temperature, to the workpiece.

The above-described substrate processing method further includes removing the first solvent; and then, in a container for a supercritical processing unit, supplying a fluorine-containing organic solvent for a supercritical processing as a fluid in a supercritical state, to the workpiece, or supplying a fluorine-containing organic solvent for a supercritical processing in a liquid or gas state, which is then brought into the supercritical state.

The present disclosure provides a substrate processing apparatus including: a chamber for a liquid processing unit configured to accommodate a workpiece; a first solvent supplying unit configured to supply a first solvent including a fluorine-free organic solvent, to the workpiece in the chamber for a liquid processing unit; a second solvent supplying unit configured to supply a second solvent including a fluorine-containing organic solvent that is not dissolved with the first solvent at a normal temperature, and is dissolved with the first solvent at a temperature higher than the normal temperature, to the workpiece in the chamber for a liquid processing unit; and a solvent heating unit configured to heat the first solvent and the second solvent to a dissolution temperature or higher to dissolve the first solvent and the second solvent.

The above-described substrate processing apparatus further includes a supercritical processing unit provided at a downstream side of the chamber for a liquid processing unit to accommodate the workpiece and supply a fluorine-containing organic solvent for a supercritical processing as a fluid in a supercritical state, to the workpiece, or supply a fluorine-containing organic solvent for a supercritical processing in a liquid or gas state, which is then brought into the supercritical state.

The present disclosure provides a non-transitory computer-readable storage medium that stores a computer program for performing a substrate processing method. The substrate processing method includes: supplying a first solvent including a fluorine-free organic solvent, to a workpiece; supplying a second solvent including a fluorine-containing organic solvent that is not dissolved with the first solvent at a normal temperature, and is dissolved with the first solvent at a temperature higher than the normal temperature; and replacing the first solvent with the second solvent while dissolving the first solvent and the second solvent by heating the first solvent and the second solvent to a dissolution temperature or higher.

According to the present exemplary embodiment, when the liquid attached to the front surface of the wafer is removed by the supercritical processing, the kinds of the fluorine-containing organic solvents to be used may be reduced as much as possible.

<Exemplary Embodiment of the Present Disclosure>

<Substrate Processing Apparatus>

First, a substrate processing apparatus according to the present disclosure will be described. As an example of the substrate processing apparatus, descriptions will be made on a liquid processing apparatus 1 including liquid processing units 2 configured to perform a liquid processing by supplying various processing liquids to a wafer W (a workpiece), which is a substrate, and supercritical processing units 3 configured to remove a dry-preventing liquid attached to the wafer W after the liquid processing by bringing the liquid into contact with a supercritical fluid (a fluid in a supercritical state).

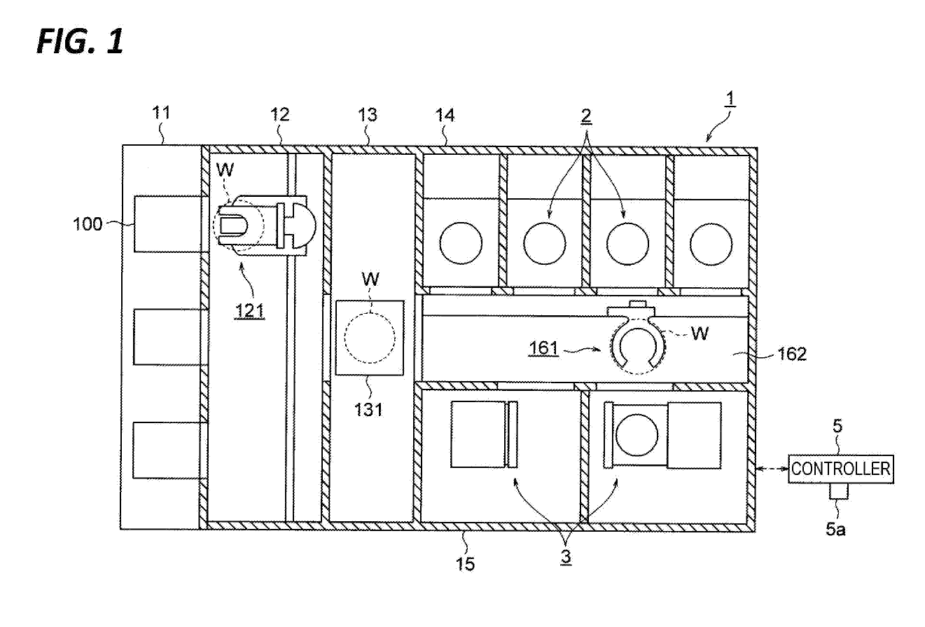

FIG. 1 is a cross-sectional plan view illustrating the whole configuration of the liquid processing apparatus 1. When viewing the figure, the left side in the figure is assumed as the front side. In the liquid processing apparatus 1, front opening unified pods (FOUPs) 100 are placed on a placing section 11, and a plurality of, for example, 300-mm wafers W stored in the FOUPs 100 are delivered between a post-stage liquid processing section 14 and a supercritical processing section 15 through a carry-in/out section 12 and a delivery section 13, and carried into the liquid processing units 2 and the supercritical processing units 3 in sequence, thereby performing a liquid processing or a processing of removing the dry-preventing liquid. In the figure, reference numeral 121 denotes a first conveyance mechanism that conveys the wafers between the FOUPs 100 and the delivery section 13, and reference numeral 131 is a delivery shelf that plays a role as a buffer on which the wafers W to conveyed among the carry-in/out section 12, the liquid processing section 14, and the supercritical processing section 15 are temporarily placed.

The liquid processing section 14 and the supercritical processing section 15 are provided across a wafer W conveyance space 162 that extends in the longitudinal direction from an opening between the conveyance space 162 and the delivery section 13. In the liquid processing section 14 provided on the left side of the conveyance space 162 when viewed from the front side, for example, four (4) liquid processing units 2 are arranged along the conveyance space 162. Meanwhile, in the supercritical processing section 15 provided on the right side of the conveyance space 162, for example, two (2) supercritical processing units 3 are arranged along the conveyance space 162.

The wafers W are conveyed among each of the liquid processing units 2, each of the supercritical processing units 3, and the delivery section 13 by the second conveyance mechanism 161 disposed in the conveyance space 162. The second conveyance mechanism 161 corresponds to a substrate conveyance unit. Here, the number of the liquid processing units 2 or the supercritical processing units 3 disposed in the liquid processing section 14 or the supercritical processing section 15 is appropriately selected depending on, for example, the number of the wafers W to be processed per unit hour, and the difference in processing time between the liquid processing units 2 and the supercritical processing units 3. The optimal layout is selected depending on the number of the liquid processing units 2 or the supercritical processing units 3 disposed.

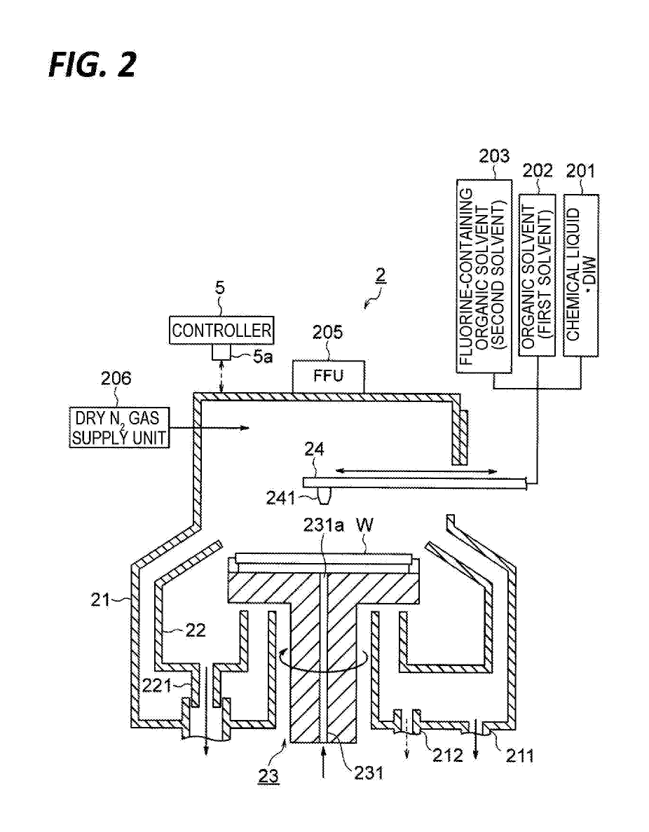

Each liquid processing unit 2 is configured as a single wafer type liquid processing unit 2 that cleans one wafer W after another by, for example, spin cleaning. As illustrated in the vertical-sectional side view of FIG. 2, the liquid processing unit 2 includes: an outer chamber 21 as a chamber for a liquid processing unit that defines a processing space; a wafer holding mechanism 23 disposed in the outer chamber and configured to rotate the wafer W around a vertical axis while holding the wafer substantially horizontally; an inner cup 22 disposed to surround the wafer holding mechanism from the lateral peripheral side thereof and configured to receive a liquid scattered from the wafer W; and a nozzle arm 24 configured to be movable between a position above the wafer W and a position retracted therefrom and provided with a nozzle 241 in the tip end portion thereof.

The nozzle 241 is connected with a processing liquid supplying unit 201 that supplies various chemical liquids, an organic solvent supplying unit (a first solvent supplying unit) 202 configured to supply a fluorine-free organic solvent (a first solvent) such as, for example, hexane, and a fluorine-containing organic solvent supplying unit (a second solvent supplying unit) 203 configured to supply a fluorine-containing organic solvent (a second solvent), which is a dry-preventing liquid, to the front surface of the wafer W. As the fluorine-containing organic solvent (the second solvent), a solvent that is different from a supercritical processing fluorine-containing organic solvent used in a supercritical processing (to be described later) is used. Further, the fluorine-free organic solvent (the first solvent) (e.g., hexane), the dry-preventing fluorine-containing organic solvent, and the supercritical processing fluorine-containing organic solvent are adopted among which a predetermined relationship exists in the boiling point or the critical temperature. Details thereof will be described later.

Further, a fan filter unit (FFU) 205 is provided in the outer chamber 21, and air cleaned from the FFU 205 is supplied to the outer chamber 21. Further, a low-humidity N₂ gas supplying unit 206 is provided in the outer chamber 21, and a low-humidity N₂ gas is supplied from the low-humidity N₂ gas supplying unit 206 to the outer chamber 21.

Further, a chemical liquid supply path 231 having an opening 231a may be formed inside the wafer holding mechanism 23, so that a rear surface cleaning of the wafer W is performed by the chemical liquid and a rinse liquid supplied therefrom. In this case, high-temperature deionized water (DIW) may be supplied to the rear surface of the wafer W using the chemical liquid supply path 231, as described later. In the bottom portion of the outer chamber 21 or the inner cup 22, an exhaust port 212 is formed to exhaust the internal atmosphere, or drain ports 221, 211 are formed to discharge the liquid scattered from the wafer W.

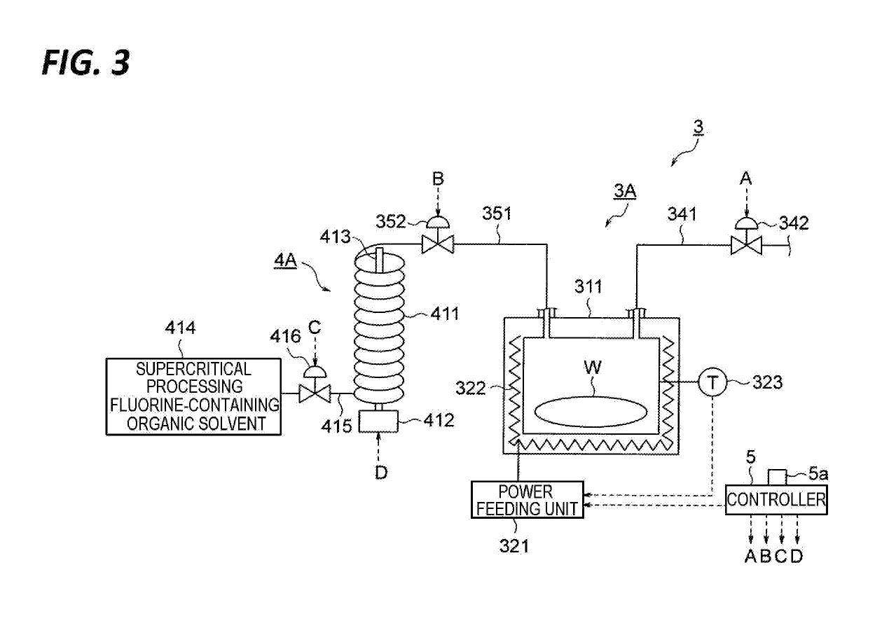

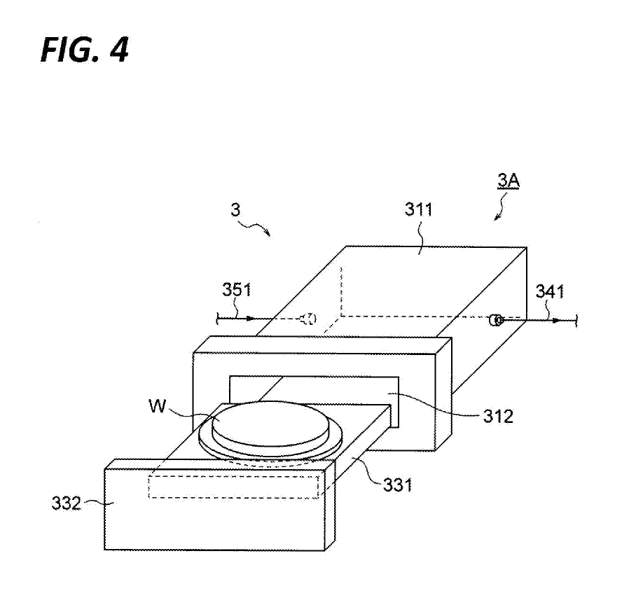

The dry-preventing fluorine-containing organic solvent (the second solvent) is supplied to the wafer W which has been subjected to the liquid processing in the liquid processing unit 2, and the wafer W is conveyed to the supercritical processing unit by the second conveyance mechanism 161, in a state where its surface is covered with the dry-preventing fluorine-containing organic solvent. In the supercritical processing unit 3, the wafer W is brought into contact with the supercritical fluid of the supercritical processing fluorine-containing organic solvent, so that the dry-preventing fluorine-containing organic solvent is removed, and the wafer W is dried. Hereinafter, the configuration of the supercritical processing unit 3 will be described with reference to FIGS. 3 and 4.

The supercritical processing unit 3 includes a processing container 3A serving as a container for the supercritical processing unit where a processing is performed to remove the dry-preventing fluorine-containing organic solvent attached to the front surface of the wafer W, and a supercritical fluid supplying unit 4A configured to supply a supercritical fluid of the supercritical processing fluorine-containing organic solvent to the processing container 3A (a supercritical processing fluorine-containing organic solvent supplying unit).

As illustrated in FIG. 4, the processing container 3A includes a case-type container body 311 formed with an opening 312 for carry-in/out of the wafer W, a wafer tray 331 capable of horizontally holding the wafer W to be processed, and a cover member 332 configured to support the wafer tray 331 and seal the opening 312 when the wafer W is carried into the container body 311.

The container body 311 is, for example, a container having a processing space with a volume of approximately 200 cm³ to 10,000 cm³, which is capable of accommodating a 300-mm wafer W, and the top of the container body 311 is connected with a supercritical fluid supply line 351 configured to supply the supercritical fluid into the processing container 3A, and a discharge line (discharge unit) 341 interposed with an opening/closing valve 342 and configured to discharge the fluid in the processing container 3A. Further, the processing container 3A is provided with a pressing mechanism (not illustrated) configured to seal the processing space by pushing the cover member 332 toward the container body 311 against an internal pressure caused by the processing fluid in a supercritical state, which is supplied into the processing space.

The container body 311 is provided with a heater 322 which is a heating unit constituted by, for example, a resistance heating element, and a temperature detecting unit 323 including, for example, a thermocouple for detecting a temperature in the processing container 3A. When the container body is heated, the processing container 3A may be heated to a predetermined temperature, so that the wafer W within the processing container 3A is heated. The heater 322 may change a caloric value by changing a power supplied from a power feeding unit 321, and control the temperature in the processing container 3A to a predetermined temperature based on the temperature detection result acquired from the temperature detecting unit 323.

The supercritical fluid supplying unit 4A is connected to an upstream side of the supercritical fluid supply line 351 interposed with an opening/closing valve 352. The supercritical fluid supplying unit 4A includes a spiral pipe 411 which is a pipe for preparing the supercritical fluid of the supercritical processing fluorine-containing organic solvent to be supplied to the processing container 3A, a supercritical processing fluorine-containing organic solvent supplying unit 414 configured to supply a liquid of the supercritical processing fluorine-containing organic solvent, which is a raw material of the supercritical fluid, to the spiral pipe 411, and a halogen lamp 413 configured to heat the spiral pipe 411 so as to bring the supercritical processing fluorine-containing organic solvent within the spiral pipe 411 into a supercritical state.

The spiral pipe 411 is, for example, a cylindrical container formed by spirally winding a stainless pipe member in the longitudinal direction, and is painted with, for example, a radiant heat-absorbing black paint in order to easily absorb radiant heat supplied from the halogen lamp 413. The halogen lamp 413 is disposed to be spaced apart from an inner wall surface of the spiral pipe 411 along a cylindrical central axis of the spiral pipe 411.

A power supply unit 412 is connected to a lower end portion of the halogen lamp 413, and the halogen lamp 413 emits heat by a power supplied from the power supply unit 412, so that the spiral pipe 411 is heated primarily by using the radiant heat. The power supply unit 412 is connected with a temperature detecting unit (not illustrated) provided in the spiral pipe 411, and may heat the inside of the spiral pipe 411 to a predetermined temperature by increasing or decreasing the power supplied to the spiral pipe 411 based on a detection temperature.

Further, a pipe member extends from the lower end portion of the spiral pipe 411 to form a reception line 415 for the supercritical processing fluorine-containing organic solvent. The reception line 415 is connected to the supercritical processing fluorine-containing organic solvent supplying unit 414 via an opening/closing valve 416 having pressure resistance. The supercritical processing fluorine-containing organic solvent supplying unit 414 includes, for example, a tank configured to store the supercritical processing fluorine-containing organic solvent in a liquid state, a liquid feeding pump, and a flow rate control mechanism.

The liquid processing apparatus 1 including the liquid processing unit 2 or the supercritical processing unit 3 configured as described above is connected to a controller 5 as illustrated in FIGS. 1 to 3. The controller 5 is constituted by a computer including a CPU (not illustrated) and a storage unit 5a. The storage unit 5a stores a program that incorporates a group of steps (commands) on a control associated with operations of the liquid processing apparatus 1, that is, operations including taking the wafer W out from the FOUP 100, performing the liquid processing of the taken wafer W in the liquid processing unit 2, subsequently, drying the wafer W in the supercritical processing unit 3, and then, carrying the wafer W into the FOUP 100. The program is stored in a storage medium such as, for example, a hard disk, a compact disk, a magneto optical disk, or a memory card, and installed into the computer therefrom.

Next, descriptions will be made on the fluorine-free solvent (e.g., hexane) as the first solvent and the dry-preventing fluorine-containing organic solvent as the second solvent, which are supplied to the front surface of the wafer W in the liquid processing unit 2, and the supercritical processing fluorine-containing organic solvent supplied to the processing container 3A in the state of the supercritical fluid in order to remove the dry-preventing fluorine-containing organic solvent from the front surface of the wafer W. Among them, the dry-preventing fluorine-containing organic solvent and the supercritical processing fluorine-containing organic solvent are fluorine-containing organic solvents that contain fluorine atoms in hydrocarbon molecules.

Examples of combinations of the fluorine-free organic solvent (e.g., hexane) (first solvent), the dry-preventing fluorine-containing organic solvent (second solvent), and the supercritical processing fluorine-containing organic solvent are listed in Table 1.

TABLE 1

| | | | Class | B.P. |
|---|---|---|---|---|
| | Maker | Product Name | Name | (° C.) |
| First Solvent | Kanto Chemical Co., Inc. | n-Hexane | | 69 |
| | Kanto Chemical Co., Inc. | 2,2,4-Trimethylpentane | | 99 |
| | Kanto Chemical Co., Inc. | n-Decane | | 169 |
| Dry-preventing | Sumitomo 3M Ltd. | FLUORINERT ® | PFC | 165 |
| Fluorine-Containing | | FC-40 | | |
| Organic Solvent | Sumitomo 3M Ltd. | FLUORINERT ® | PFC | 174 |
| (Second Solvent) | | FC-43 | | |
| | Sumitomo 3M Ltd. | FLUORINERT ® | PFC | 128 |
| | | FC-3283 | | |
| | Solvay Solexis Inc. | GALDEN ® HT200 | PFE | 200 |
| | Solvay Solexis Inc. | GALDEN ® | PFE | 170 |
| Supercritical | Sumitomo 3M Ltd. | FLUORINERT ® FC-72 | PFC | 56 |
| Processing Fluorine- | | | | |
| Containing Organic | | | | |
| Solvent | | | | |

In the class name in Table 1, PFC (perfluorocarbon) represents a fluorine-containing organic solvent obtained by substituting all hydrogen in hydrocarbon with fluorine, and PFE (perfluoroether) represents a fluorine-containing organic solvent obtained by substituting all hydrogen in hydrocarbon having an ether bond in the molecule with fluorine.

When a fluorine-containing organic solvent is selected as the supercritical processing fluorine-containing organic solvent among the fluorine-containing organic solvents, a solvent having a higher boiling point (lower vapor pressure) than that of the supercritical processing fluorine-containing organic solvent is selected as the dry-preventing fluorine-containing organic solvent. Therefore, the amount of the fluorine-containing organic solvent volatilized from the front surface of the wafer W may be reduced while the wafer W is conveyed from the liquid processing unit 2 to the supercritical processing unit 3, as compared with a case where the supercritical processing fluorine-containing organic solvent is adopted as the dry-preventing liquid.

The boiling point (standard boiling point) of the dry-preventing fluorine-containing organic solvent may be 100° C. or higher (e.g., 174° C.), which is higher than that of hexane. Since the dry-preventing fluorine-containing organic solvent having a boiling point of 100° C. or higher is less volatilized during the conveyance of the wafer W, the front surface of the wafer W may be maintained in a wet state for approximately dozens of seconds to 10 minutes only by supplying a small amount of fluorine-containing organic solvent (e.g., approximately 0.01 cc to 5 cc in the case of a 300-mm wafer W or approximately 0.02 cc to 10 cc in the case of a 450-mm wafer W). For reference, IPA needs to be supplied in an amount of approximately 10 cc to 50 cc to maintain the front surface of the wafer W in the wet state for the same time as above. However, hexane and the dry-preventing fluorine-containing organic solvent (e.g., FC43) are not dissolved at a normal temperature (5° C. to 35° C.) (JIS Z8703), but dissolved with each other (dissolution temperature) by heating to a temperature higher than the normal temperature (e.g., 60° C.).

Further, as for the supercritical processing fluorine-containing organic solvent used as the supercritical fluid, when a fluorine-containing organic solvent which has a boiling point lower than that of the dry-preventing fluorine-containing organic solvent is selected, a fluorine-containing organic solvent capable of forming the supercritical fluid at a low temperature may be used, and the fluorine atoms may be suppressed from being released due to decomposition of the fluorine-containing organic solvent.

<Actions of the Present Exemplary Embodiment>

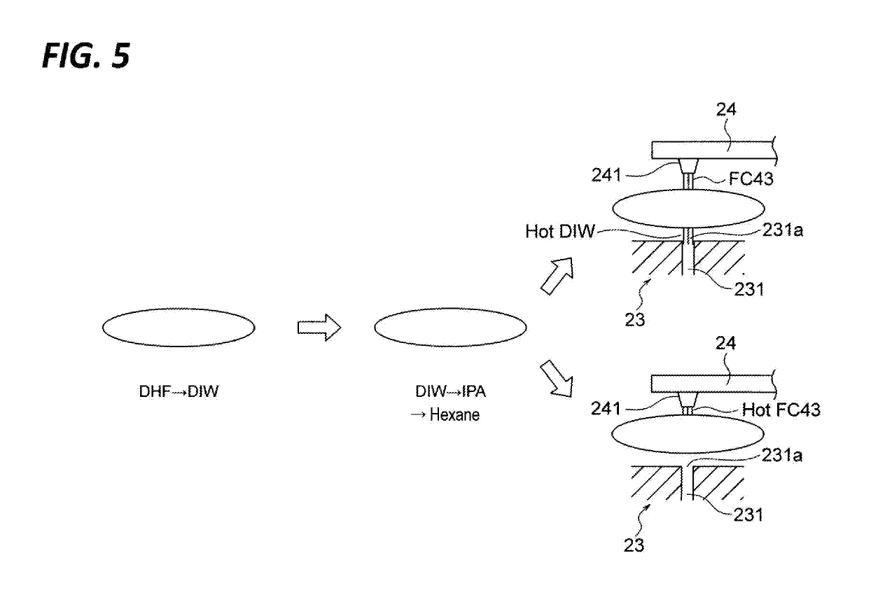

Next, descriptions will be made on the actions of the present exemplary embodiment configured above with reference to FIG. 5.

In the present exemplary embodiment, descriptions will be made on actions in a case where hexane is used as the fluorine-free organic solvent (first solvent), FC43 is used as the dry-preventing fluorine-containing organic solvent (second solvent), and FC72 is used as the supercritical processing fluorine-containing organic solvent.

First, the wafer W taken out from the FOUP 100 is carried into the outer chamber 21 of the liquid processing section 14 through the carry-in/out section 12 and the delivery section 13, and delivered to the wafer holding mechanism 23 of the liquid processing unit 2. Subsequently, various processing liquids are supplied from the processing liquid supplying unit 201 to the front surface of a rotating wafer W, thereby performing a liquid processing.

As illustrated in FIG. 5, in the liquid processing, wet cleaning for removing particles or organic contaminants by, for example, diluted hydrofluoric acid (DHF) which is an acidic chemical liquid, and rinse cleaning by deionized water (DIW) which is a rinse liquid, are performed.

When the liquid processing by the chemical liquid or the rinse liquid is completed, DIW remaining between patterns WP of the front surface of the wafer W and on the rear surface is replaced with IPA by supplying IPA (a water-soluble organic solvent) first from the organic solvent supplying unit (first solvent supplying unit) 202 to the front surface of the rotating wafer W (see FIG. 5). When the liquid between the patterns WP of the front surface of the wafer W is sufficiently replaced with IPA, the supply of IPA from the organic solvent supplying unit 202 is stopped, and instead, hexane (the first solvent) is supplied from the organic solvent supplying unit 202 to the front surface of the wafer W. In this manner, the IPA between the patterns WP of the wafer W is replaced with the hexane. Next, the dry-preventing fluorine-containing organic solvent (FC43) is supplied from the fluorine-containing organic solvent supplying unit (second solvent supplying unit) 203 to the front surface of the rotating wafer W, and then, the rotation of the wafer W is stopped. After the rotation is stopped, the wafer W comes into a state where the patterns WP of the front surface are covered with the dry-preventing fluorine-containing organic solvent. In this case, since IPA has high affinity for DIW, the DIW may be replaced with the IPA. In addition, since hexane has high affinity for IPA, the IPA may be replaced with the hexane. Meanwhile, FC43 is not dissolved with hexane at a normal temperature (5° C. to 30° C.). Thus, the hexane is not mixed with the FC43 in the FC43, and is present, especially, between patterns WP of the wafer W.

However, while the dry-preventing fluorine-containing organic solvent (FC43) is supplied from the fluorine-containing organic solvent supplying unit 203 to the front surface of the wafer W, hot (80° C.) DIW is supplied from the chemical liquid supply path 231 of the wafer holding mechanism 23 to the rear surface of the wafer W through the opening 231a. When the hot DIW is supplied to the rear surface of the wafer W in this manner, the hexane and FC43 supplied to the front surface of the wafer W are heated up to the above-mentioned dissolution temperature (60° C.) or higher, so that the hexane and the FC43 are dissolved with each other. Then, the hexane on the wafer W, especially the hexane between the patterns WP is replaced gradually with FC43 by further supplying FC43 from the fluorine-containing organic solvent supplying unit 203 to the front surface of the wafer W.

As illustrated in FIG. 5, the wafer W which has been subjected to the liquid processing is carried out from the liquid processing unit 2 and conveyed to the supercritical processing unit 3 by the second conveyance mechanism 161. At this time, the hexane on the wafer W is replaced with the dry-preventing fluorine-organic organic solvent, and the fluorine-containing organic solvent remains between the patterns WP. Meanwhile, since a fluorine-containing organic solvent having a high boiling point (low vapor pressure) is used as the dry-preventing fluorine-containing organic solvent, it is possible to reduce the amount of the fluorine-containing organic solvent volatilized from the front surface of the wafer W during the period of the conveyance.

At a timing before the wafer W is carried into the processing container 3A of the supercritical processing unit 3, the supercritical fluid supplying unit 4A opens the opening/closing valve 416 to send a predetermined amount of the liquid of the supercritical processing fluorine-containing organic solvent form the supercritical processing fluorine-containing organic solvent supplying unit 414, and then, closes the opening/closing valves 352, 416 to seal the spiral pipe 411. At this time, the liquid of the supercritical processing fluorine-containing organic solvent is accumulated in the lower side of the spiral pipe 411, and when the supercritical processing fluorine-containing organic solvent is heated, a space where the vaporized supercritical processing fluorine-containing organic solvent expands is left in the upper side of the spiral pipe 411.

As such, the liquid processing is completed, and the wafer W of which the front surface is covered with the dry-preventing fluorine-containing organic solvent is placed on the wafer tray 331 of the processing container 3A of the supercritical processing unit 3, and then, carried into the supercritical processing unit 3 by closing the cover member 332.

Next, in the processing container 3A of the supercritical processing unit 3, the wafer W is heated by the heater 322, thereby heating the dry-preventing fluorine-containing organic solvent (FC43).

In this state, when power feeding from the power supply unit 412 to the halogen lamp 413 is started such that the halogen lamp 413 generates heat, the inside of the spiral pipe 411 is heated so that the supercritical processing fluorine-containing organic solvent vaporizes, and further, as the temperature and the pressure increase and reach the critical temperature and the critical pressure, the solvent becomes a supercritical fluid.

When the supercritical processing fluorine-containing organic solvent in the spiral pipe 411 is supplied to the processing container 3A, the temperature and the pressure increases up to a temperature and a pressure that are capable of maintaining the critical pressure and the critical temperature.

Thereafter, in a sealed state where the cover member 332 is closed, before the dry-preventing fluorine-containing organic solvent (FC43) on the front surface of the wafer W is dried, the opening/closing valve 352 of the supercritical fluid supply line 351 is opened to supply the supercritical fluid of the supercritical processing fluorine-containing organic solvent (FC72) from the supercritical fluid supplying unit 4A.

When the supercritical fluid is supplied from the supercritical fluid supplying unit 4A such that the inside of the processing container 3A becomes the supercritical fluid atmosphere of the supercritical processing fluorine-containing organic solvent (FC72), the opening/closing valve 352 of the supercritical fluid supply line 351 is closed. The supercritical fluid supplying unit 4A turns off the halogen lamp 433, discharges the fluid in the spiral pipe 411 through a depressurization line (not illustrated), and accepts the supercritical processing fluorine-containing organic solvent (FC72) of a liquid from the supercritical processing fluorine-containing organic solvent supplying unit 414 in order to prepare for the next supercritical fluid.

Meanwhile, the processing container 3A is in a sealed state where the supply of the supercritical fluid from the outside is stopped, and the inside is filled with the supercritical fluid of the supercritical processing fluorine-containing organic solvent (FC72). At this time, focusing on the front surface of the wafer W in the processing container 3A, the supercritical fluid of the supercritical processing fluorine-containing organic solvent (FC72) is in contact with the liquid of the dry-preventing fluorine-containing organic solvent (FC43) which has entered into the patterns WP. In this case, the inside of the processing container 3A is at a temperature of 200° C. and a pressure of 2 MPa.

Thus, when the contact of the liquid of the dry-preventing fluorine-containing organic solvent and the supercritical fluid is maintained, the dry-preventing fluorine-containing organic solvent (FC43) and the supercritical processing fluorine-containing organic solvent (FC72), which are miscible with each other, are mixed so that the liquid between the patterns WP are replaced with the supercritical fluid. Eventually, the liquid of the dry-preventing fluorine-containing organic solvent is removed from the front surface of the wafer W, an atmosphere of a supercritical fluid of the mixture of the dry-preventing fluorine-containing organic solvent and the supercritical processing fluorine-containing organic solvent is formed around the patterns WP. At this time, since the liquid of the dry-preventing fluorine-containing organic solvent can be removed at a relatively low temperature close to the supercritical temperature of the supercritical processing fluorine-containing organic solvent, the fluorine-containing organic solvent is substantially not decomposed, and a small amount of hydrogen fluoride that damages the patterns is generated.

Thus, after the lapse of time required to remove the liquid of the dry-preventing fluorine-containing organic solvent from the front surface of the wafer W, the opening/closing valve 342 of the discharge line 341 is opened to discharge the fluorine-containing organic solvent from the inside of the processing container 3A. At this time, the amount of the heat supplied from the heater 322 is adjusted, for example, such that the inside of the processing container 3A is maintained at a temperature equal to or higher than the supercritical temperature of the supercritical processing fluorine-containing organic solvent. As a result, it is possible to discharge the mixed fluid in the supercritical state or gas state without liquefying the dry-preventing fluorine-containing organic solvent having a boiling point higher than the supercritical temperature of the supercritical processing fluorine-containing organic solvent, and to avoid generation of pattern collapse when discharging the fluid.

When the processing with the supercritical fluid is completed, the wafer W, which has been dried by removing the liquid, is taken out by the second conveyance mechanism 161, and housed in the FOUP 100 through the carry-in/out section 12. Then, a series of processings on the wafer W is completed. In the liquid processing apparatus 1, the above-described processings are sequentially performed on respective wafers W in the FOUP 100.

As described above, according to the present exemplary embodiment, DIW may be replaced with IPA by supplying IPA to the wafer W after supplying DIW to the wafer W. In addition, the IPA may be replaced with hexane by supplying hexane to the IPA. Subsequently, the dry-preventing fluorine-containing organic solvent (FC43) is supplied to the hexane replaced in this manner. In this case, the hexane and the FC43 are not dissolved at the normal temperature, but when the hexane and the FC43 are heated to the dissolution temperature or higher, which is higher than the normal temperature, the hexane and the FC43 are dissolved with each other, so that the hexane is replaced gradually with the FC43. Thereafter, the supercritical processing fluorine-containing organic solvent (FC72) is supplied to the wafer W to mix the FC43 and the FC72, and then, the supercritical processing is performed on the wafer W. Therefore, the FC43 and the FC72 may be efficiently removed from the front surface of the wafer W without damaging to the patterns.

As such, it is not necessary to sequentially replace from the IPA on the wafer W to the FC43 by supplying separate fluorine-containing organic solvent having affinity for both the IPA and the FC43, onto the wafer W supplied with the IPA, but after the IPA is supplied to the wafer W, when the hexane and the FC43 are heated to the dissolution temperature or higher while sequentially supplying the hexane and the FC43, the hexane and the FC43 are dissolved, and thus, the hexane may be replaced with the FC43. Since it is not necessary to use separate fluorine-containing organic solvent having affinity for both the IPA and the FC43, the kinds of expensive fluorine-containing organic solvents may be reduced as much as possible.

<Modification>

Next, a modification of the present disclosure will be described.

The present modification is merely different in the method of heating the dry-preventing fluorine-containing organic solvent (FC43) supplied to the wafer W, and other configurations are substantially similar to the above-described exemplary embodiment illustrated in FIGS. 1 to 5.

That is, the above-described exemplary embodiment was exemplified by the case where the rear surface of the wafer W was heated by the hot DIW to dissolve the hexane and the dry-preventing fluorine-containing organic solvent (FC43), thereby replacing the hexane with the FC43, but not limited thereto. The hexane may be replaced with the FC43 by supplying the dry-preventing fluorine-containing organic solvent (FC43), which is heated to a high temperature, for example, 60° C. or higher, to the wafer W to dissolve the hexane and the dry-preventing fluorine-containing organic solvent (FC43) (see FIG. 5).

Meanwhile, the above-described exemplary embodiment was exemplified by the case where the supercritical fluid was supplied to the supercritical processing unit 3 from the outside, but not limited thereto. The supercritical processing unit 3 may be supplied with a supercritical fluorine-containing organic solvent in a gas or liquid state, which is then brought into a supercritical state in the supercritical processing unit 3.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
supplying a first solvent including a fluorine-free organic solvent, to a workpiece;
supplying a second solvent including a fluorine-containing organic solvent that is not dissolved with the first solvent at a normal temperature, and is dissolved with the first solvent at a temperature higher than the normal temperature; and
replacing the first solvent with the second solvent while dissolving the first solvent and the second solvent by heating the first solvent and the second solvent to a dissolution temperature or higher.

2. The substrate processing method of claim 1, wherein the dissolution temperature of the first solvent and the second solvent is 40° C. or higher.

3. The substrate processing method of claim 1, wherein the first solvent and the second solvent are heated by heating the workpiece.

4. The substrate processing method of claim 1, wherein the first solvent and the second solvent are heated by supplying the second solvent at a high temperature, to the workpiece.

5. The substrate processing method of claim 1, further comprising:
removing the first solvent; and then
in a container for a supercritical processing unit, supplying a fluorine-containing organic solvent for a supercritical processing as a fluid in a supercritical state, to the workpiece, or supplying a fluorine-containing organic solvent for a supercritical processing in a liquid or gas state, which is then brought into the supercritical state.

6. A substrate processing apparatus comprising:
a chamber for a liquid processing unit configured to accommodate a workpiece;
a first solvent supplying unit configured to supply a first solvent including a fluorine-free organic solvent, to the workpiece in the chamber for a liquid processing unit;
a second solvent supplying unit configured to supply a second solvent including a fluorine-containing organic solvent that is not dissolved with the first solvent at a normal temperature, and is dissolved with the first solvent at a temperature higher than the normal temperature, to the workpiece in the chamber for a liquid processing unit; and
a solvent heating unit configured to heat the first solvent and the second solvent to a dissolution temperature or higher to dissolve the first solvent and the second solvent.

7. The substrate processing apparatus of claim 6, further comprising:
a supercritical processing unit provided at a downstream side of the chamber for a liquid processing unit to accommodate the workpiece and supply a fluorine-containing organic solvent for a supercritical processing as a fluid in a supercritical state, to the workpiece, or supply a fluorine-containing organic solvent for a supercritical processing in a liquid or gas state, which is then brought into the supercritical state.

8. A non-transitory computer-readable storage medium that stores a computer program for performing a substrate processing method,
wherein the substrate processing method includes:
supplying a first solvent including a fluorine-free organic solvent, to a workpiece;
supplying a second solvent including a fluorine-containing organic solvent that is not dissolved with the first solvent at a normal temperature, and is dissolved with the first solvent at a temperature higher than the normal temperature; and
replacing the first solvent with the second solvent while dissolving the first solvent and the second solvent by heating the first solvent and the second solvent to a dissolution temperature or higher.
